(19) United States
(12) Patent Application Publication
(10) Pub. No.: US 2026/0190910 A1
(43) Pub. Date: Jul. 2, 2026

(54) SEMICONDUCTOR MANUFACTURING APPARATUS AND CONTROL METHOD OF WAFER TEMPERATURE

(71) Applicant: Hitachi High-Tech Corporation, Minato-ku, Tokyo (JP)

(72) Inventors: Takahiro IWAI, Tokyo (JP); Masaki YAMADA, Tokyo (JP); Keisuke AKINAGA, Tokyo (JP)

(21) Appl. No.: 18/842,165

(22) PCT Filed: Jul. 21, 2023
(86) PCT No.: PCT/JP2023/026876

§ 371 Date: Aug. 28, 2024

(51) Int. Cl. H10P 72/00; H10P 72/76

(52) U.S. Cl. CPC H10P 72/0436; H10P 72/0421; H10P 72/7612

(57) ABSTRACT

Provided is a technique for facilitating the temperature control of a wafer in a processing chamber into which a gas is introduced.

A semiconductor manufacturing apparatus includes a wafer heater using an electromagnetic wave, and a control circuit. The control circuit uses information representing the relation between the species of a gas introduced into a processing chamber, the pressure of the gas in the periphery of a wafer, the height of a pusher pin determining the distance between the wafer and a stage, the output of the heater, the target temperature of the wafer, and a target temperature reaching time until the temperature of the wafer reaches the target temperature to previously determine the height of the pusher pin such that the target temperature reaching time is an allowable time or less with respect to the set species of the gas, the set pressure of the gas, and the set target temperature of the wafer. The control circuit controls the height of the pusher pin to the determined height, and then controls at least one of the output of the heater and the height of the pusher pin.

### TECHNICAL FIELD

The present invention relates to a semiconductor manufacturing apparatus and a control method of a wafer temperature.

### BACKGROUND ART

In the isotropic etching process of three-dimensional semiconductor processing, the necessity for gas etching is increasing. In particular, it is known that the gas etching in a high temperature and high pressure environment has an advantage in view of increasing the etching speed, that is, of shortening the predetermined etching time. In the gas etching, physical parameters, such as the pressure of the gas and the temperature of the wafer, significantly contribute to the chemical reaction, so that it is important to control those parameters.

As a method of heating the wafer in order to control the temperature of the wafer, a method of heating a stage supporting the wafer is typical. On the other hand, in the case of this method, the thermal capacity of the stage is large, and it takes time to heat the wafer, so that the throughput of the wafer processing tends to be lowered. On the contrary, for example, Patent Literature 1 describes a method by which an electromagnetic wave such as an infrared light is emitted to a wafer to heat the wafer at higher speed.

### CITATION LIST

### Patent Literature

Patent Literature 1: Japanese Patent No. 6488164

### SUMMARY OF INVENTION

### Technical Problem

However, it has been found, according to the result of the study by the present inventors, that when the method by which the electromagnetic wave is emitted to heat the wafer is applied in the processing chamber into which the processing gas is introduced, the temperature of the wafer is changed according to the pressure of the gas, so that the temperature control of the wafer is difficult. When the temperature control of the wafer in the processing chamber into which the gas is introduced is difficult, it becomes difficult to shorten the time required to cause the temperature of the wafer to reach the target temperature, so that the productivity cannot be improved in the semiconductor processing using the gas, for example, in the gas etching and the like.

An object of the present invention is to provide a technique for facilitating the temperature control of a wafer in a processing chamber into which a gas is introduced.

### Solution to Problem

An embodiment of the present invention provides a semiconductor manufacturing apparatus including a processing chamber, a heater that is disposed outside the processing chamber and heats a wafer inside the processing chamber by an electromagnetic wave, a stage that is disposed inside the processing chamber and is positioned below the wafer, a wafer support mechanism that has at least a portion disposed inside the processing chamber, supports the wafer, is configured to be able to be lifted or lowered, and can adjust the distance between the wafer and the stage, a gas supply and exhaust system that can adjust the pressure of a gas inside the processing chamber, a memory circuit that stores relation information representing the relation between the output of the heater, the species of the gas, the pressure of the gas inside the processing chamber, the target temperature of the wafer, the distance between the wafer and the stage, and a time until the temperature of the wafer reaches the target temperature; and a control circuit that uses the relation information to determine, on the basis of the set species of the gas, the set pressure of the gas, and the set target temperature of the wafer, the distance between the wafer and the stage such that the time until the temperature of the wafer reaches the set target temperature is a set time or less, and controls the wafer support mechanism such that the distance between the wafer and the stage is the determined distance.

An embodiment of the present invention provides a control method of a wafer temperature including a step by which a wafer support mechanism that is disposed inside a processing chamber and is configured to be able to be lifted or lowered supports a wafer above a stage, a step by which a gas supply and exhaust system adjusts the pressure of a gas inside the processing chamber, a step by which a memory circuit stores relation information representing the relation between the output of a wafer heater using an electromagnetic wave, the species of the gas, the pressure of the gas inside the processing chamber, the target temperature of the wafer, the distance between the wafer and the stage, and a time until the temperature of the wafer reaches the target temperature, a step by which a control circuit uses the relation information to determine, on the basis of the set species of the gas, the set pressure of the gas, and the set target temperature of the wafer, the distance between the wafer and the stage such that the time until the temperature of the wafer reaches the set target temperature is a set time or less, and a step by which the control circuit controls the wafer support mechanism such that the distance between the wafer and the stage is the determined distance.

### Advantageous Effects of Invention

According to an embodiment of the present invention, it is possible to provide a technique for facilitating the temperature control of a wafer in a processing chamber into which a gas is introduced. Note that objects, configurations, and effects other than the above will be apparent from the description of the following embodiments.

### BRIEF DESCRIPTION OF DRAWINGS

FIG. 1 is a diagram illustrating an example of a graph that represents the relation between the average temperature of a wafer and the pressure of a gas in the periphery of the wafer under a constant heating condition.

FIG. 2 is a diagram schematically illustrating an example of the main portion of a semiconductor manufacturing apparatus.

FIG. 3 is a diagram schematically illustrating an example of the main portion of the semiconductor manufacturing apparatus.

FIG. 4 is a side view schematically illustrating the configuration of the semiconductor manufacturing apparatus according to a first embodiment.

FIG. 5 is a diagram illustrating an example of the dependence of the height of a pusher pin with respect to the target temperature reaching time of the wafer.

FIG. 6 is a graph schematically illustrating the relation between the target temperature of the wafer and the target temperature reaching time in the case where the height of the pusher pin is set in a plurality of ways to heat the wafer.

FIG. 7 is a diagram illustrating the relation between the target temperature of the wafer and the target temperature reaching time being different according to the height of the pusher pin.

FIG. 8 is a diagram illustrating the relation between the target temperature of the wafer and the target temperature reaching time being different according to the height of the pusher pin.

FIG. 9 is a flowchart illustrating an example of the flow of the processes of the semiconductor manufacturing apparatus according to the first embodiment, and is a diagram schematically illustrating the pressure of the gas in a processing chamber, the height of the pusher pin, and the change with time in the output of a wafer heater during an etching process.

FIG. 10 is a time chart schematically illustrating the flow of an example of an operation according to the first embodiment of the present invention.

FIG. 11 is a cross-sectional view illustrating the schematic configuration of a semiconductor manufacturing apparatus according to a second embodiment.

FIG. 12 is a flowchart illustrating an example of the flow of the operation of the semiconductor manufacturing apparatus according to the second embodiment.

FIG. 13 is a graph schematically illustrating the relation between the change with time in the height of the pusher pin and the change with time in the temperature of the wafer according to a third embodiment.

### DESCRIPTION OF EMBODIMENTS

### The Details of the Study by the Present Inventors

Semiconductor manufacturing processes include, for example, processes, such as pattern transfer, etching, cleaning, and leveling, with respect to a wafer configured of silicon, gallium arsenide, and the like. Here, an apparatus and a method used in the etching process will be noted.

As described above, it has been found that when the method by which the electromagnetic wave is emitted to heat the wafer is applied to the wafer in the processing chamber into which the processing gas is introduced, the temperature of the wafer is changed according to the pressure of the gas in the processing chamber, so that it is not easy to control the temperature of the wafer. As an example, when the semiconductor manufacturing apparatus performing the etching is in a high pressure environment in which the pressure of the gas in the processing chamber is high, the temperature control of the wafer by the wafer heater using the electromagnetic wave becomes difficult. Note that here, the gas is, for example, an argon gas, a helium gas, or the like. The high pressure environment is, for example, an environment such that the pressure of the gas inside the processing chamber is a predetermined pressure of 10 Pa or more and an atmospheric pressure or less. In addition, the temperature of the wafer is, for example, a predetermined temperature of 100° C. or more and 700° C. or less.

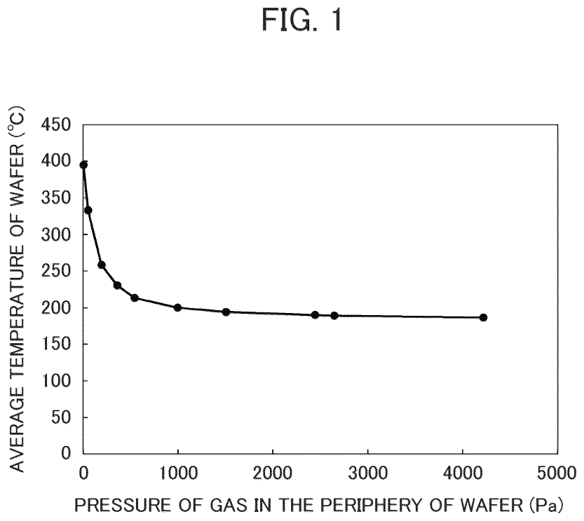

FIG. 1 is a diagram illustrating an example of a graph that represents the relation between the average temperature of the wafer and the pressure of the gas in the periphery of the wafer under a constant heating condition. For example, as illustrated in FIG. 1, when the pressure of the gas in the periphery of the wafer is increased under the constant heating condition, the average temperature of the wafer is lowered. In addition, the relation between the pressure of the gas in the periphery of the wafer and the average temperature of the wafer is not linear, and when the pressure of the gas in the periphery of the wafer is gradually increased, the average temperature of the wafer is first abruptly lowered, and thereafter, is gently lowered.

This mechanism will be described with reference to the drawings.

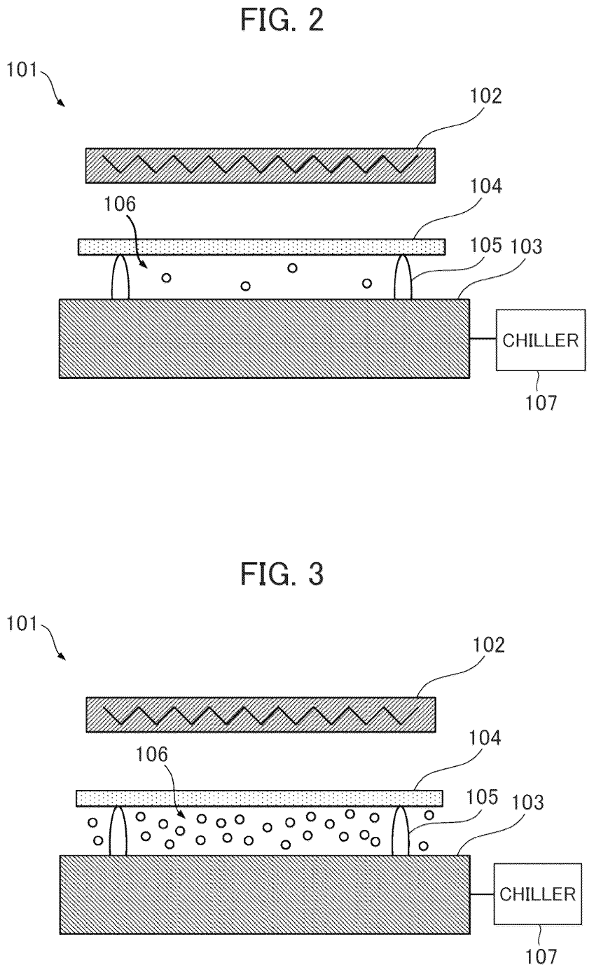

FIGS. 2 and 3 are diagrams schematically illustrating an example of the main portion of the semiconductor manufacturing apparatus. As illustrated in FIGS. 2 and 3, a semiconductor manufacturing apparatus 101 includes a wafer heater 102 using an electromagnetic wave, a stage 103 without an electrostatic chuck mechanism, and a proximity pin 105 that is disposed with respect to the upper side of the stage 103 and supports a wafer 104. A circle represented between the wafer 104 and the stage 103 schematically represents a gas molecule 106. A chiller 107 is connected to the stage 103, and can cool the stage 103. Note that the height of the proximity pin 105 in these drawings is exaggeratively drawn to facilitate the understanding of the description.

As illustrated in FIG. 2, in a low pressure environment in which the pressure of the gas is relatively low, the number of gas molecules 106 that are media performing heat exchange between the wafer 104 and the stage 103 is small. Therefore, the cooling efficiency of the wafer 104 on the stage 103 is lowered, and the heating of the wafer 104 by the wafer heater 102 is facilitated. On the other hand, in a high pressure environment in which the gas pressure is relatively high, as illustrated in FIG. 3, the number of gas molecules 106 that are media performing heat exchange between the wafer 104 and the stage 103 is increased. Therefore, the heat transmission efficiency between the wafer 104 and the stage 103 is increased, and the wafer temperature is lowered. Consequently, there are problems that, for example, the output of the wafer heater 102 is insufficient to be unable to achieve the desired processing process, and that it takes time to heat the wafer 104, thereby leading to the lowered productivity in the semiconductor processing.

In view of such circumstances, the present inventors have found, as a result of intensive studies, a technique for facilitating the control of the wafer temperature in the processing chamber into which the gas is introduced.

Hereinbelow, embodiments of the present invention will be described with reference to the drawings. Note that in the following embodiments, the elements, members, or portions of the same configuration are indicated by the same reference numerals, and unless required, the repeated description thereof is omitted. In addition, the following embodiments are illustrative only, and do not limit the technical scope of the present invention at all.

### First Embodiment

A first embodiment of the present invention will be described.

### <The Configuration Example of the Semiconductor Manufacturing Apparatus According to the First Embodiment>

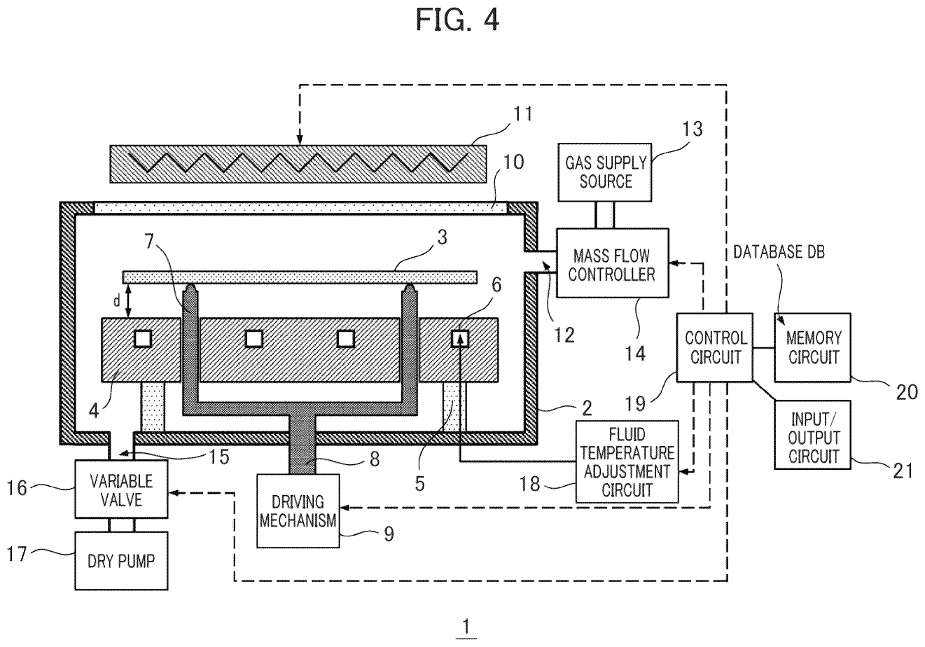

FIG. 4 is a side view schematically illustrating the configuration of a semiconductor manufacturing apparatus 1 according to the first embodiment. As illustrated in FIG. 4, the semiconductor manufacturing apparatus 1 includes, for example, a processing chamber 2 that is made of an aluminum material and the like and has a substantially cylindrical vessel shape having an upper portion in which an opening is formed. The processing chamber 2 is provided with a stage 4 having a plate shape for placing a wafer 3 in its inside. The stage 4 is connected to the bottom portion of the processing chamber 2 by a support member 5. The stage 4 is a proximity stage without an electrostatic chuck mechanism.

A channel 6 in which a fluid such as water flows is provided inside the stage 4, and the temperature of the fluid flowing in the channel 6 is adjusted, so that the temperature of the top surface of the stage 4 can be adjusted. Outside the processing chamber 2, a fluid temperature adjustment circuit 18 that adjusts the temperature of the fluid flowing in the channel 6 is installed. The channel 6 and the fluid temperature adjustment circuit 18 are connected so as to penetrate through the side wall or the bottom portion of the processing chamber 2. Sealing is made between the channel 6 and the processing chamber 2. Note that the fluid, the channel 6, and the fluid temperature adjustment circuit 18 are an example of the “temperature adjustment system” of the present application.

In the stage 4, a plurality of through holes that penetrate in the up-down direction, that is, in the vertical direction, are formed. A plurality of pusher pins 7 are provided so as to be inserted through these through holes. For example, three or more sets of the pusher pins 7 and the through holes therefor are provided. At the tips of the upper portions of these pusher pins 7, the wafer 3 is placed. Below the stage 4, a drive shaft 8 is provided so as to penetrate through the bottom portion of the processing chamber 2 in the up-down direction. These pusher pins 7 are connected to the drive shaft 8.

Below the processing chamber 2, a driving mechanism 9 is provided. The drive shaft 8 is connected to the driving mechanism 9, and is configured to be able to be lifted or lowered. The driving mechanism 9 is configured of, for example, a stepping motor, an actuator, and the like. The drive shaft 8 is driven in the up-down direction, that is, is lifted or lowered, by the driving mechanism 9, so that it is possible to adjust the height of the pusher pins 7 to control the distance d between the wafer 3 and the top surface of the stage 4 supported by the pusher pins 7.

Sealing is made between the drive shaft 8 and the through hole of the bottom portion of the processing chamber 2 through which the drive shaft 8 is inserted, and when the opening formed in the upper portion of the processing chamber 2 is closed, the airtightness inside the processing chamber 2 is held. In addition, the driving mechanism 9 is not limited to the stepping motor, and a simpler driving mechanism may be used.

Note that the pusher pins 7, the drive shaft 8, and the driving mechanism 9 are an example of the “wafer support mechanism” of the present application.

On the upper side, that is, the ceiling side, of the processing chamber 2, a top plate 10 is installed. The top plate 10 is configured of, for example, quartz and the like, and has a characteristic transmitting an electromagnetic wave therethrough. Above the top plate 10, for example, a wafer heater 11 that emits an electromagnetic wave such as an infrared light toward the wafer 3 is installed.

In the side wall of the processing chamber 2, an opening 12 for supplying the gas to the inside of the processing chamber 2 is formed. Outside the processing chamber 2, a gas supply source 13 including, for example, a gas cylinder and the like, is installed. The opening 12 and the gas supply source 13 are communicated through a mass flow controller 14. By the operation of the mass flow controller 14, the flow rate of the gas can be controlled, and the gas can be introduced to the inside of the processing chamber 2.

In the bottom portion of the processing chamber 2, an opening 15 for discharging the gas and the particles inside the processing chamber 2 is formed. Outside the processing chamber 2, a dry pump 17 for suctioning the gas and the particles is installed. The opening 15 and the dry pump 17 are connected through a variable valve 16. During the operation of the dry pump 17, the gas and the particles inside the processing chamber 2 are discharged by the operation of the variable valve 16, and the gas pressure inside the processing chamber 2 can be controlled. Note that the opening 12, the gas supply source 13, the mass flow controller 14, the opening 15, the variable valve 16, and the dry pump 17 are mechanisms that can adjust the pressure of the gas inside the processing chamber 2, and are an example of the “gas supply and exhaust system” of the present application.

The semiconductor manufacturing apparatus 1 includes a control circuit 19, a memory circuit 20, and an input/output circuit 21. The memory circuit 20 is a circuit that stores various information necessary for the processes. In the memory circuit 20, a database DB regarding the processing condition of the wafer in the semiconductor manufacturing apparatus 1 is stored. The control circuit 19 refers to the database DB stored in the memory circuit 20, and controls the fluid temperature adjustment circuit 18, the driving mechanism 9, the wafer heater 11, the mass flow controller 14, and the variable valve 16. The input/output circuit 21 is electrically connected to the control circuit 19, receives an input from a user to transmit information to the control circuit 19, and outputs information transmitted from the control circuit 19 toward the user.

The control circuit 19 is configured of, for example, a semiconductor integrated circuit and the like, such as a CPU (Central Processing Unit) and an MCU (Micro Controller Unit). The memory circuit 20 is configured of, for example, a RAM (Random Accesses Memory), a ROM (Read Only Memory), an SSD (Solid State Drive), an HDD (Hard Disk Drive), and the like. The input/output circuit 21 is configured of, for example, a keyboard, a mouse, a monitor display or a liquid crystal touch panel, and the like.

### <The Creation Example of the Database>

Then, the creation example of the database DB will be described. Note that the database DB is an example of the “relation information” of the present application.

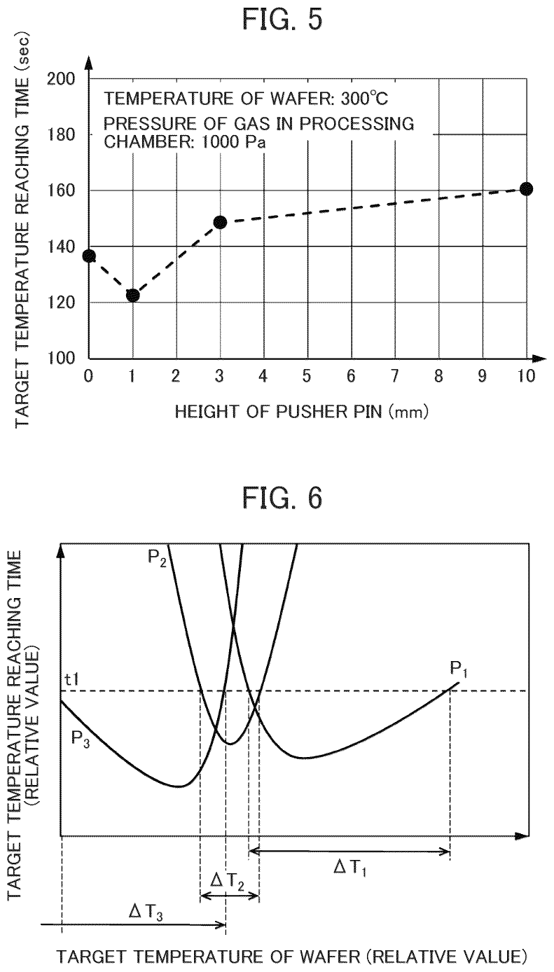

FIG. 5 is a diagram illustrating an example of the dependence of the height of the pusher pin with respect to the target temperature reaching time of the wafer. Here, the target temperature reaching time means time required for the temperature of the wafer to reach the target temperature. The example illustrated in FIG. 5 represents the result obtained when an experiment is performed under the following condition.

The temperature of the wafer is measured by a thermocouple, and the information of the measured temperature of the wafer is used to adjust the output of an infrared lamp as the wafer heater by PID control such that the temperature of the wafer is 300° C. The argon gas is introduced into the processing chamber, and the opening degree of the variable valve is controlled, so that the pressure in the processing chamber, that is, the pressure of the gas in the periphery of the wafer, is held at a pressure of 1000 Pa. The temperature of the top surface of the stage is adjusted to 20° C. It is found that when in this state, the height of the pusher pin, that is, the distance between the top surface of the stage and the back surface of the wafer is 1 mm, the target temperature reaching time of the wafer is the shortest. In this example, although the PID control is performed, the height of the pusher pin such that the target temperature reaching time of the wafer is shortened according to the pressure of the gas and the temperature of the wafer is found to be present.

FIG. 6 is a graph schematically illustrating the relation between the target temperature of the wafer and the target temperature reaching time in the case where the height of the pusher pin is set in a plurality of ways to heat the wafer. The graph of FIG. 6 illustrates an example in the case where the height of the pusher pin is set to three ways of P1, P2, and P3. The relation between the heights P1, P2, and P3 of the pusher pin is P1>P2>P3, the P1 is the highest, and the P3 is the lowest. From the graph illustrated in FIG. 6, it is found that the temperature of the wafer such that the target temperature reaching time is the shortest is present at each pusher pin height, and the target temperature reaching time can be represented by a function having a minimum value with the target temperature of the wafer as a parameter.

Here, it is possible to determine wafer temperature ranges ΔT1, ΔT2, and ΔT3 such that when time t1 is set as the reference of the target temperature reaching time, the target temperature reaching time is the set time t1 or less at the respective pusher pin heights P1, P2, and P3. Since the wafer temperature range such that the target temperature reaching time of the wafer is the time t1 or less is different for each pusher pin height, when an allowable reference is set such that the target temperature reaching time is the time t1 or less, the height of the pusher pin that is relatively suitable so as to satisfy the allowable reference can be determined on the basis of the target temperature of the desired wafer.

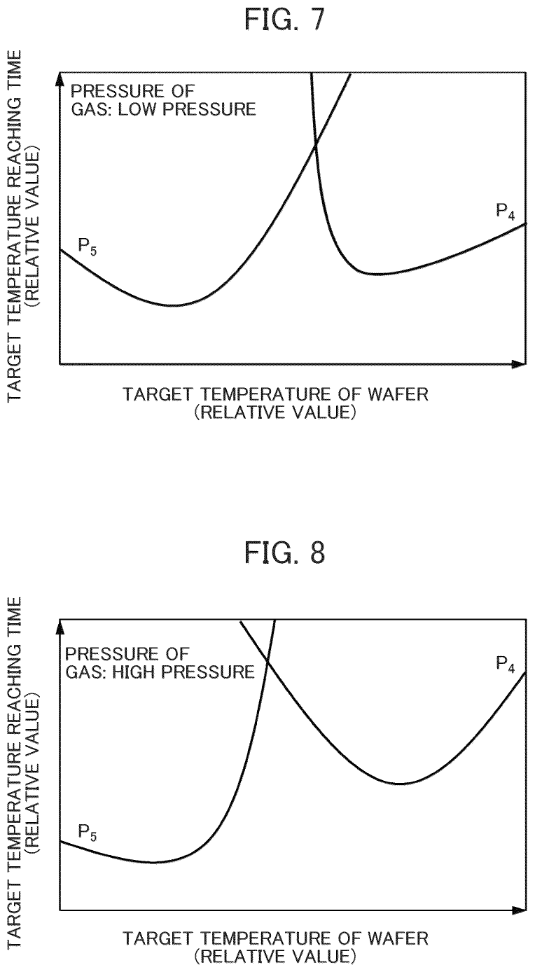

FIGS. 7 and 8 are diagrams illustrating the relation between the target temperature of the wafer and the target temperature reaching time being different according to the height of the pusher pin. FIGS. 7 and 8 schematically illustrate the relation between the target temperature of the wafer and the target temperature reaching time in the case where the height of the pusher pin is set to P4 and P5 to heat the wafer. In addition, FIG. 7 is a diagram in the case where the pressure of the gas in the processing chamber is a relatively low pressure, and FIG. 8 is a diagram in the case where the pressure of the gas in the processing chamber is a relatively high pressure. Here, the relation between the heights P4 and P5 of the pusher pin is P4>P5, and the P4 is higher than the P5.

When as illustrated in FIGS. 2 and 3, the pressure of the gas is changed, the heat transmission efficiency between the wafer and the stage is changed, and the relation between the temperature of the wafer and the target temperature reaching time of the wafer is changed even at the same height of the pusher pin. The height of the pusher pin is changed stepwise, the relation between the target temperature of the wafer and the target temperature reaching time is examined, and this is performed under various conditions of the species of the gas, the pressure of the gas, the output of the heater, and the like. By doing so, the relation between the target temperature of the wafer and the target temperature reaching time under various conditions can be made into a database. Then, it is possible to, by referring to the database, select the optimum height of the pusher pin and the optimum output condition of the heater such that the target temperature reaching time is the shortest with respect to the desired species of the gas, the desired pressure of the gas in the processing chamber, and the desired target temperature of the wafer.

The database DB created in this way is previously stored in the memory circuit 20. Note that the database DB may be, for example, a table and the like in which the proper height of the pusher pin and the proper output of the wafer heater are associated with an arbitrary combination of the species of the gas, the pressure of the gas, and the target temperature of the wafer. In addition, the database DB may be a function or an algorithm in which the species of the gas, the pressure of the gas, and the target temperature of the wafer are inputs, and the proper height of the pusher pin and the proper output of the wafer heater are outputs. Alternatively, the database DB may be information representing the relation itself between the respective parameters, such as the species of the gas, the pressure of the gas, the target temperature of the wafer, the height of the pusher pin, and the output of the wafer heater.

### <The Flow of the Processes of the Semiconductor Manufacturing Apparatus According to the First Embodiment>

Next, the flow of the processes of the semiconductor manufacturing apparatus 1 having the above configuration will be described.

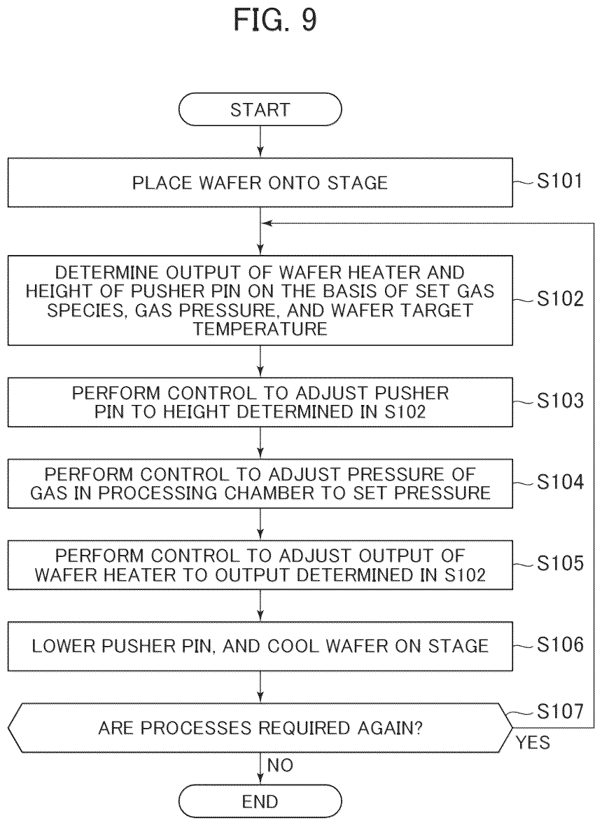

FIG. 9 is a flowchart illustrating an example of the flow of the processes of the semiconductor manufacturing apparatus 1 according to the first embodiment.

As illustrated in FIG. 9, first, in step S101, the wafer is placed onto the stage. Specifically, the robot or the like conveys the wafer 3 from the load lock chamber to the processing chamber 2, and places the wafer 3 onto the stage 4. Note that the control circuit 19 controls the fluid temperature adjustment circuit to hold the temperature of the stage 4 at the set temperature, for example, 20° C.

Next, in step S102, the output of the wafer heater and the height of the pusher pin are determined on the basis of the set species of the gas, the set pressure of the gas in the processing chamber 2, and the set target temperature of the wafer. Specifically, the control circuit 19 refers to the database DB, and determines, with respect to the set species of the gas, the set pressure of the gas, and the set target temperature of the wafer, the output of the wafer heater 11 and the height of the pusher pin 7 such that the target temperature reaching time is the set allowable time or less.

Then, in step S103, the control to adjust the pusher pin to the height determined in S102 is performed. Specifically, the control circuit 19 controls the driving mechanism 9 to adjust the height of the pusher pin to be the height determined in step S102.

Then, in step S104, the control to adjust the pressure in the processing chamber to the set pressure is performed. Specifically, the control circuit 19 controls the gas flow rate of the mass flow controller 14 connected to the gas supply source 13 and the valve opening degree of the variable valve 16 connected to the dry pump 17 being operated, introduces the gas into the processing chamber 2, and adjusts the pressure of the gas in the inside to be the set pressure.

Then, in step S105, the control to adjust the output of the wafer heater to the output determined in S102 is performed. Specifically, the control circuit 19 controls the wafer heater 11 to adjust the output of the wafer heater 11 to the output determined in step S102, thereby heating the wafer 3.

When the heating of the wafer is ended, in step S106, the process for lowering the pusher pin to cool the wafer on the stage is performed. Specifically, by controlling the driving mechanism 9 and the fluid temperature adjustment circuit 18, the control circuit 19 lowers the pusher pin 7 until the wafer 3 is placed onto the stage, adjusts the temperature of the stage 4, and cools the wafer 3 on the stage 4.

Then, in step S107, it is judged whether or not the processes are required again. Specifically, on the basis of the set sequence, the presence or absence of the transmission of an error signal, or the like, the control circuit 19 judges whether or not the processes are repeated, as needed. When it is judged that the processes are repeated (S107: Yes), the processing step shifts to step S102, and when it is judged that the processes are not repeated (S107: No), the etching process of the wafer 3 is ended.

Note that when the etching process of the wafer 3 is ended, the control circuit 19 controls the respective portions to stop the supply of the gas into the processing chamber 2, the output of the wafer heater 11, and the like, and the robot unloads the wafer 3 from the processing chamber 2.

<The Pressure of the Gas, the Height of the Pusher Pin, and the Change with Time in the Output of the Wafer Heater>

The pressure of the gas, the height of the pusher pin, and the change with time in the output of the wafer heater during the etching process will be described.

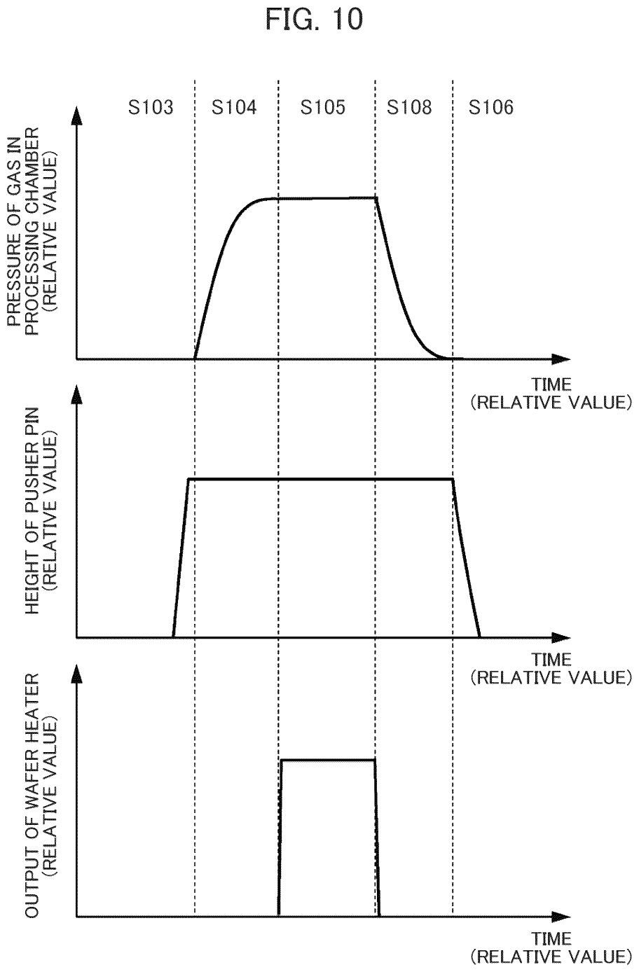

FIG. 10 is a diagram schematically illustrating the pressure of the gas in the processing chamber, the height of the pusher pin, and the change with time in the output of the wafer heater during the etching process. Each step number in the upper portion corresponds to the time zone of the step whose number in the flowchart illustrated in FIG. 9 is indicated.

As illustrated in FIG. 10, in the time zone corresponding to S103, the pusher pin 7 is lifted, and is adjusted to the height determined in S102. In the time zone corresponding to step S104, the gas is introduced into the processing chamber 2, and the pressure of the gas in the processing chamber 2 is adjusted to the set pressure. In addition, the height of the pusher pin 7 is maintained. In the time zone corresponding to step S105, the output of the wafer heater 11 is adjusted to the output determined in S102. In addition, the pressure of the gas in the processing chamber 2 and the height of the pusher pin 7 are maintained. In the time zone corresponding to step S106, the gas in the processing chamber 2 is discharged, and the pressure of the gas is lowered. The pusher pin 7 is lowered, and the tip portions thereof supporting the wafer 3 are positioned below the top surface of the stage 4. The output of the wafer heater 11 is dropped to zero.

Note that in the cooling of the wafer in step S106, when the up-down movement, that is, the lifting or lowering, of the pusher pin 7, is performed in the high pressure environment, shift may be caused between the wafer 3 and the stage 4 due to the influence of the gas molecules present between the back surface of the wafer 3 and the top surface of the stage 4. To reduce the wafer shift, step S108 that is a step for lowering the pressure of the gas in the processing chamber 2 may be provided to between steps S105 and S106.

According to such the first embodiment, the technique for facilitating the temperature control of the wafer in the processing chamber into which the gas is introduced can be provided. In more detail, according to the first embodiment, it is possible to, by referring to the database, previously determine, on the basis of the set species of the gas, the set pressure of the gas inside the processing chamber 2, and the set target temperature of the wafer 3, the height of the pusher pin 7 and the output of the wafer heater 11 such that the target temperature reaching time required to cause the temperature of the wafer 3 to reach the target temperature for stabilization is shortened. Thus, in the wide gas pressure region and the wide wafer temperature region, the temperature of the wafer 3 can be caused to immediately reach the target temperature, thereby enhancing the productivity of the semiconductor processing. As a result, the improvement in the throughput of the semiconductor processing and the improvement in the controllability of the etching can be expected.

Note that the effect by the first embodiment is particularly effective in the high temperature environment or in the high pressure environment in which the temperature control of the wafer is difficult. For example, the effect by the first embodiment is particularly effective when the temperature of the wafer is the predetermined temperature of 100° C. or more and 700° C. or less, or when the pressure of the gas is the predetermined pressure of 10 Pa or more and the atmospheric pressure or less.

### Second Embodiment

### <The Configuration Example of a Semiconductor Manufacturing Apparatus According to a Second Embodiment>

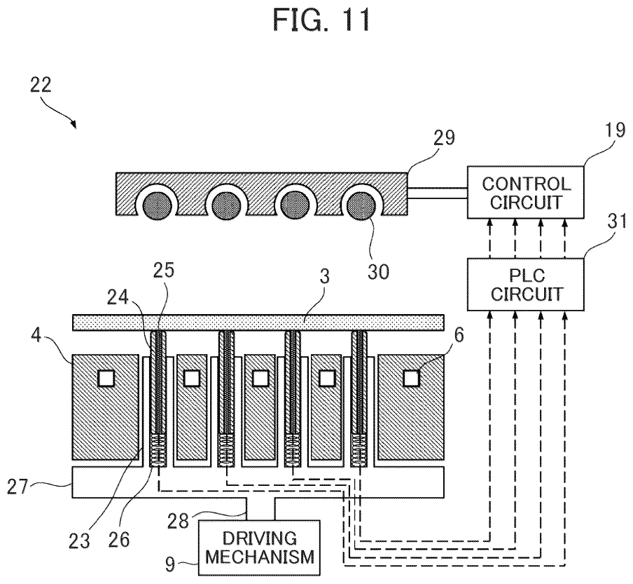

FIG. 11 is a cross-sectional view illustrating the schematic configuration of the semiconductor manufacturing apparatus according to the second embodiment. In a semiconductor manufacturing apparatus 22 illustrated in FIG. 11, the processing chamber 2, the support member 5, the top plate 10, the gas supply and exhaust system, and the like are omitted, and the forms, functions, and the like of the omitted portions are the same as the corresponding portions of the semiconductor manufacturing apparatus 1.

In the semiconductor manufacturing apparatus 22, a cylinder 23 extending in the up-down direction and a pusher pin 24 stored in the cylinder 23 are disposed so as to pass through the through hole penetrating through the stage 4 in the up-down direction. A plurality of, for example, four or more pusher pins 24 and cylinders 23 are disposed. Inside each of the pusher pins 24, a temperature sensor 25 such as a thermocouple is provided. When the wafer 3 is supported by the plurality of pusher pins 24, a plurality of temperature sensors 25 come into contact with the back surface of the wafer 3. In the bottom portion side inside the cylinder 23, for example, a cushioning material 26 such as a member enclosing a spring and compressed air is sealed. When the wafer 3 is supported by the plurality of pusher pins 24, the cushioning materials 26 are distorted by the weight of the wafer 3, and the contactability between the wafer 3 and the respective temperature sensors 25 is improved.

The cylinder 23 in which the pusher pin 24 and the cushioning material 26 are stored in its inside is connected to a support mechanism 27, and the support mechanism 27 is connected to a drive shaft 28. The drive shaft 28 is connected to the driving mechanism 9 provided below the processing chamber. The driving mechanism 9 lifts or lowers the drive shaft 28 in the up-down direction, so that the height of the pusher pin 24 can be adjusted to control the distance between the back surface of the wafer 3 supported by the pusher pin 24 and the top surface of the stage 4.

On the ceiling side of the semiconductor manufacturing apparatus 22, for example, a wafer heater 29 using the electromagnetic wave of an infrared lamp and the like is installed. In this embodiment, the wafer hater 29 includes a plurality of lamps. In more detail, the water heater 29 includes a configuration in which a plurality of infrared lamps 30 in an annular shape, that is, in a ring shape, are concentrically disposed.

Temperature signals corresponding to the respective positions on the back surface of the wafer 3 detected by the temperature sensors 25 are transmitted through a PLC circuit 31 to the control circuit 19. The control circuit 19 independently adjusts the respective outputs of the plurality of infrared lamps 30 on the basis of the received temperature signals, and brings the temperature of the wafer 3 closer to the set target temperature. This adjustment may be performed by so-called feedback control. Each of the infrared lamps 30 is disposed at a position so as to correspond to each position at which the temperature measurement is performed in the plane of the wafer 3. The control circuit 19 identifies, from the received temperature signals, a temperature distribution in the plane of the wafer 3, and independently controls the respective outputs of the infrared lamps 30 on the basis of the identified temperature distribution, thereby being capable of adjusting the temperature distribution in the plane of the wafer 3.

### <The Flow of the Processes of the Semiconductor Manufacturing Apparatus According to the Second Embodiment>

Next, the flow of the processes of the semiconductor manufacturing apparatus 22 having the above configuration will be described.

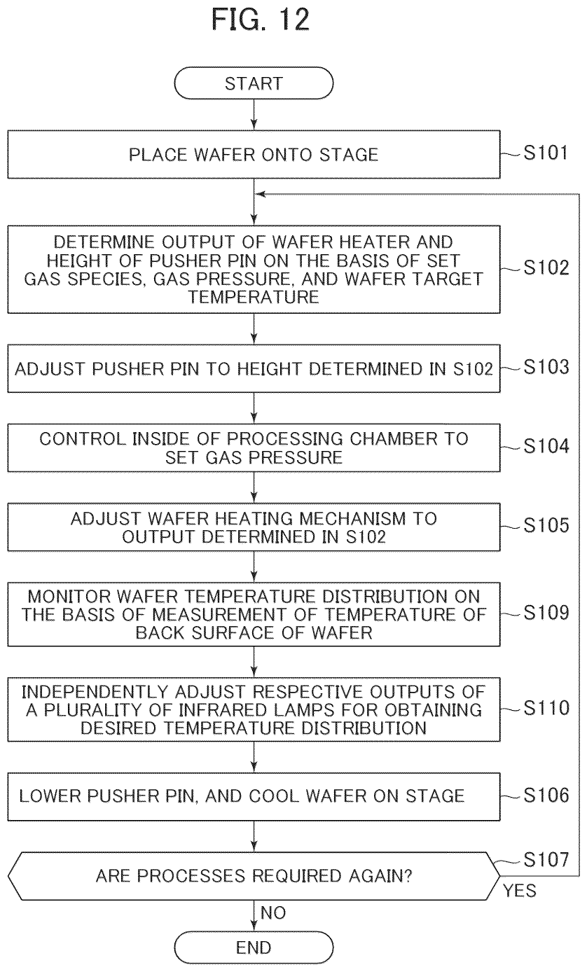

FIG. 12 is a flowchart illustrating an example of the flow of the operation of the semiconductor manufacturing apparatus 22 according to the second embodiment.

Steps S101 to S105 and S106 and S107 in the flowchart according to the second embodiment illustrated in FIG. 12 are the same processes as steps S101 to S107 in the flowchart according to the first embodiment illustrated in FIG. 9. The semiconductor manufacturing apparatus 22 according to the second embodiment has a feature in the processes in steps S109 to S110.

In step S109, the wafer temperature distribution is monitored on the basis of the measurement of the temperature of the back surface of the wafer. Specifically, the control circuit 19 receives, through the PLC circuit 31, temperature information from the temperature sensors 25 provided in the pusher pins 24 coming into contact with the back surface of the wafer 3 during the heating of the wafer 3 by the wafer heater 29. The control circuit 19 measures and monitors the temperature distribution in the plane of the wafer 3 on the basis of the received temperature information.

In step S110, on the basis of the information of the monitored temperature distribution in the plane of the wafer 3, the control circuit 19 independently controls the respective outputs of the plurality of infrared lamps 30 such that the temperature of the wafer 3 is close to the target temperature, that is, such that the wafer 3 has the desired temperature distribution.

According to such the second embodiment, it is possible to previously determine the height of the pusher pin 24 and the output of the wafer heater 29 such that the target temperature reaching time is shortened, and in addition to that, the temperature distribution on the wafer surface can also be controlled during heating, so that in addition to the effect by the first embodiment, the productivity of the semiconductor manufacturing can be improved, for example, the uniformity of the temperature distribution in the plane of the wafer can be improved, and the processing dimension correction in the arbitrary portion in the plane can be made.

### Third Embodiment

A semiconductor manufacturing apparatus according to a third embodiment has the same configuration as the semiconductor manufacturing apparatus according to the second embodiment. However, the wafer heater according to the third embodiment may be the same as the wafer heater 11 according to the first embodiment. In the semiconductor manufacturing apparatus according to the third embodiment, the output of the wafer heater 29 is made constant, and the height of the pusher pin 24 is controlled at high speed, so that the temperature of the wafer 3 is controlled.

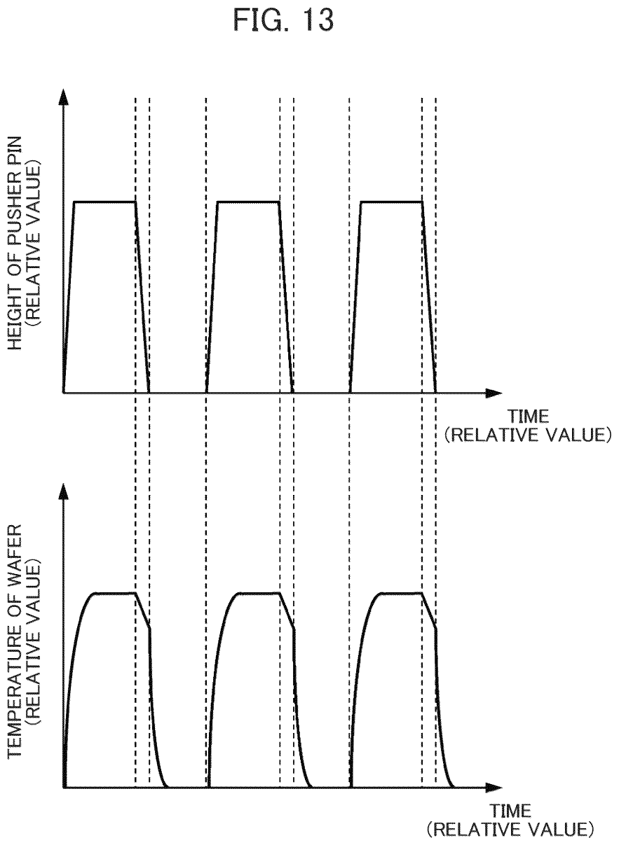

FIG. 13 is a graph schematically illustrating the relation between the change with time in the height of the pusher pin and the change with time in the temperature of the wafer according to the third embodiment. As illustrated in FIG. 13, when the height of the pusher pin 24 is increased, the distance between the wafer 3 and the wafer heater 29 is decreased to increase the heating effect from the wafer heater 29, and the distance between the wafer 3 and the stage 4 is increased to lower the cooling effect from the stage 4, so that the temperature of the wafer 3 is increased. On the other hand, when the height of the pusher pin 24 is decreased, the distance between the wafer 3 and the wafer heater 29 is increased to lower the heating effect from the wafer heater 29, and the distance between the wafer 3 and the stage 4 is decreased to increase the cooling effect from the stage 4, so that the temperature of the wafer 3 is lowered.

By adopting the driving mechanism 9 that can drive the drive shaft 28 at high speed, the height of the pusher pin 24 can be controlled at high speed. The output of the wafer heater 29 is made constant, and the height of the pusher pin 24 is controlled at high speed to adjust the temperature of the wafer 3, so that the temperature of the wafer 3 can be controlled at higher speed as compared with the case where the output of the wafer hater 29 is controlled to adjust the temperature of the wafer 3.

According to such the third embodiment, the heating and the cooling of the wafer 3 can be performed at high speed, so that the processing time can be further shortened, and the throughput of the semiconductor manufacturing can be further improved.

Various embodiments of the present invention have been described above, but the present invention is not limited to the above embodiments, and includes various modification examples. In addition, the above embodiments have been described in detail for simply describing the present invention, and are not necessarily required to include all the described configurations. In addition, a portion of the configuration of an embodiment can be replaced with the configurations of other embodiments, and besides, the configuration of an embodiment can also be added with the configurations of other embodiments. All of these belong to the category of the present invention. Further, the numerical values and the like included in the specification and the drawings are also illustrative only, and even when different numerical values and the like are used, the effect of the present invention is not deteriorated.

### LIST OF REFERENCE SIGNS

1: semiconductor manufacturing apparatus,
2: processing chamber,
3: wafer,
4: stage,
5: support member,
6: channel,
7: pusher pin,
8: drive shaft,
9: driving mechanism,
10: top plate,
11: wafer heater,
12: opening,
13: gas supply source,
14: mass flow controller,
15: opening,
16: variable valve,
17: dry pump,
18: fluid temperature adjustment circuit,
19: control circuit,
20: memory circuit,
21: input/output circuit,
22: semiconductor manufacturing apparatus,
23: cylinder,
24: pusher pin,
25: temperature sensor,
26: cushioning material,
27: support mechanism,
30: infrared lamp,
31: PLC circuit

1. A semiconductor manufacturing apparatus comprising:
a processing chamber;
a heater that is disposed outside the processing chamber and heats a wafer inside the processing chamber by an electromagnetic wave;
a stage that is disposed inside the processing chamber and is positioned below the wafer;
a wafer support mechanism that has at least a portion disposed inside the processing chamber, supports the wafer, is configured to be able to be lifted or lowered, and can adjust the distance between the wafer and the stage;
a gas supply and exhaust system that can adjust the pressure of a gas inside the processing chamber;
a memory circuit that stores relation information representing the relation between the output of the heater, the species of the gas, the pressure of the gas inside the processing chamber, the target temperature of the wafer, the distance between the wafer and the stage, and a time until the temperature of the wafer reaches the target temperature; and
a control circuit that uses the relation information to determine, on the basis of the set species of the gas, the set pressure of the gas, and the set target temperature of the wafer, the distance between the wafer and the stage such that the time until the temperature of the wafer reaches the set target temperature is a set time or less, and controls the wafer support mechanism such that the distance between the wafer and the stage is the determined distance.

2. The semiconductor manufacturing apparatus according to claim 1,
wherein the wafer support mechanism has
a plurality of pusher pins that support the wafer, and
a plurality of temperature sensors in which at least one each of the temperature sensors is disposed in each of the plurality of pusher pins, and
on the basis of the temperature of the back surface of the wafer measured by the plurality of temperature sensors, the control circuit controls the output of the heater such that the temperature of the wafer is close to the set target temperature.

3. The semiconductor manufacturing apparatus according to claim 2,
wherein the heater includes a plurality of lamps, and
the control circuit independently controls the respective outputs of the plurality of lamps on the basis of the temperature distribution of the back surface of the wafer measured by the plurality of temperature sensors.

4. The semiconductor manufacturing apparatus according to claim 3,
wherein the plurality of lamps respectively have annular shapes, and are concentrically disposed.

5. The semiconductor manufacturing apparatus according to claim 1,
wherein the stage is connected to a temperature adjustment system that can adjust the temperature of the stage, and
the control circuit controls the temperature adjustment system such that the stage holds the set temperature.

6. The semiconductor manufacturing apparatus according to claim 1,
wherein the wafer support mechanism has
a plurality of pusher pins that support the wafer, and
a plurality of temperature sensors in which at least one each of the temperature sensors is disposed in each of the plurality of pusher pins, and
on the basis of the temperature of the back surface of the wafer measured by the plurality of temperature sensors, the control circuit controls the height of the pusher pin of the wafer support mechanism such that the temperature of the wafer is close to the set target temperature.

7. The semiconductor manufacturing apparatus according to claim 1, wherein
the set pressure of the gas is 10 Pa or more and an atmospheric pressure or less.

8. A control method of a wafer temperature comprising:
a step by which a wafer support mechanism that is disposed inside a processing chamber and is configured to be able to be lifted or lowered supports a wafer above a stage;
a step by which a gas supply and exhaust system adjusts the pressure of a gas inside the processing chamber;
a step by which a memory circuit stores relation information representing the relation between the output of a wafer heater using an electromagnetic wave, the species of the gas, the pressure of the gas inside the processing chamber, the target temperature of the wafer, the distance between the wafer and the stage, and a time until the temperature of the wafer reaches the target temperature;
a step by which a control circuit uses the relation information to determine, on the basis of the set species of the gas, the set pressure of the gas, and the set target temperature of the wafer, the distance between the wafer and the stage such that the time until the temperature of the wafer reaches the set target temperature is a set time or less; and
a step by which the control circuit controls the wafer support mechanism such that the distance between the wafer and the stage is the determined distance.
